(19) United States
(12) Patent Application Publication
(10) Pub. No.: US 2020/0240037 A1
(43) Pub. Date: Jul. 30, 2020

(54) DEVICE FOR PRODUCING HIGH PRESSURES IN SOLID MEDIA

(71) Applicant: ECODIAMOND GMBH, Kavelstorf (DE)

(72) Inventors: Boris FEIGELSON, Springfield, VA (US); Andrey KOSTYAEV, Wiendorf (DE)

(21) Appl. No.: 16/757,376

(22) PCT Filed: Oct. 15, 2018
(86) PCT No.: PCT/EP2018/078102

§ 371 Date: Apr. 18, 2020

(30) Foreign Application Priority Data
Oct. 19, 2017 (EP) 17197358.9

(51) Int. Cl. C30B 1/12; C30B 29/04; C30B 7/10; B01J 3/06

(52) U.S. Cl. CPC C30B 1/12; C30B 29/04; B01J 2203/0655; B01J 3/067; C30B 7/10

(57) ABSTRACT

A device (1) for generating high pressures in solid and liquid media is described. The device (1) includes a lower shell-shaped body half (2) and an upper shell-shaped body half (3). The device (1) further includes a lower elastic membrane (6) and an upper elastic membrane (7), which are each inserted into the lower body half (2) and into the upper body half (3), respectively. The respective body half (2, 3) and the respective membrane (6, 7) inserted into it each surround a pressure chamber (62, 73). The device (1) furthermore includes an opening and a channel (14) in the lower body half (2), in order to attach an oil line from an oil pump to the device and to pump the oil into the pressure chamber between the lower body half (2) and the elastic membrane (6) inserted into it. The pressure chambers (62, 73) in the lower body half (2) and in the upper body half (3) communicate by means of a line. The device (1) is distinguished in that the line connects the pressure chambers (62, 73) in the lower body half (2) and the upper body half (3) permanently with one another in both the open and the closed state of the device. The device is furthermore distinguished in that it includes a pipeline, which is embodied in the form of a helical spring line (17) and extends outside the lower shell-shaped body half (2) and the upper shell-shaped body half (3).

The invention relates to a device for generating high pressures in solid and liquid media in accordance with the preamble to claim 1.

High pressures are required for many process engineering procedures in the production of various materials. There are many pressure devices that are capable of generating pressures and temperatures that suffice for diamond synthesis.

H. T. Hall (1980), High Pressure Techniques, John Wiley & Sons, Utah, is cited as prior art.

From the prior art (U.S. Pat. No. 3,118,177, RU 2077375, U.S. Pat. No. 7,887,631), devices for growing synthetic diamonds are also known. They contain a lower and an upper shell-shaped body half and a split sphere, comprising eight sphere sectors that act on a central growth chamber, can be inserted between the half shells. In other embodiments, a second stage of the octahedral sphere sectors can be employed instead of the growth chamber. This second stage is located in an octahedral void generated by eight sphere sectors of the split sphere. In this case, the growth chamber is placed in a cubic chamber. The cubic chamber is created by the second stage of the octahedral sphere sectors, so that by the reduction in the surface area a considerable amplification of pressure is exerted on the raw mixture for the diamond growth that is located in the growth chamber.

The pressure in the growth chamber is generated by transmitting the oil pressure between the body halves and an elastic membrane to sphere sectors of the split sphere via the membrane. The sphere sectors then transmit this pressure to the growth chamber. In another embodiment, the sphere sectors of the split sphere transmit the pressure to the smaller sphere sectors of a sphere in the second stage. The smaller sphere sectors then transmit the pressure into the growth chamber. The movement of the sphere sectors is triggered by the oil pressure. During operation, a symmetrical motion of the sphere sectors toward the center point of the split sphere takes place.

In the devices known previously from U.S. Pat. Nos. 3,118,177 and 7,887,631, the sphere sectors are accommodated in a common pressure chamber filled with a hydraulic oil. To gain access to the growth chamber, the pressure chamber must first be emptied by expelling the hydraulic oil. This makes handling and dealing with the equipment very complicated and uneconomical.

In the device known from RU 2077375, the pressure chamber is divided into two parts. A first pressure chamber is accommodated in the upper body half and a second pressure chamber in the lower body half. During the operation of the device, the device is closed. The two body halves are joined together at a common parting plane. When the two body halves are put together, the pressure chambers communicate with one another via an oil line. The oil line consists of two rectilinear connection line segments. One of the two straight connection line segments is embodied in each of the two body halves. The longitudinal axes of the connection line segments are perpendicular to the common parting plane between the two body halves. If the two body halves are located such that one rests on the other, the two connection line segments open into one another. To open the device, the two body halves are taken apart. Once the two body halves are taken apart, the oil line is disconnected. The two connection line segments then no longer open into one another; instead, each opens into the open air. If the two body halves are moved away from one another, there is accordingly no connection between the two pressure chambers. In order to prevent all the hydraulic fluid from escaping if the two body halves are moved apart from one another, the connection line segments are provided with valves. To reach the growth chamber, the two body halves can as a result be moved apart from one another without requiring that the hydraulic fluid be expelled. The valves that are at high pressure in operation of the growth chamber have required moving parts in order to function. The moving parts of the valves are subject to considerable wear at the high pressure. Accordingly, the valves cannot ensure complete tightness as the two body halves move apart from one another. This leads to oil leakage losses not only during operation of the growth chamber at the high pressure that then prevails, but also when the device is opened for the sake of gaining access to the growth chamber. An additional disadvantage is that, at least during pressure buildup and reduction, the pressure at the valves becomes largely the same as the wear of the moving parts of the valves increases. The result is asymmetrical movement of the sphere sectors that form dies. The asymmetrical movement causes skewed positions between the sphere sectors. At the high pressure that is necessary for the operation of the growth chamber, even very slightly skewed positions lead, cause a breach of the internal dies and/or an escape of material in the growth chamber. This makes the synthetic product created in the growth chamber unusable.

With the above prior art as the point of departure, the object of the invention is to create a device which can generate high pressures, in both solid and fluid media. The pressures and temperatures for the synthesis of diamonds and cubic boron nitride, in order to produce synthetic diamonds and cubic boron nitride, thus have to be provided. This device must be safe in operation and easier to use and should also produce synthetic products that are homogeneous in quality.

This object is attained by the features of claim 1.

The invention uses a plurality of pressure means in order to generate pressures in solid and fluid media. Such a device has a lower shell-shaped body half and an upper shell-shaped body half as well as a lower elastic membrane and an upper elastic membrane, which are each inserted into the lower body half and into the upper body half. Each body half and the respective membrane inserted into it is surrounded by a respective pressure chamber. Furthermore, the device has an opening and a channel in the lower body half in order to attach an oil line from an oil pump to the device and to pump the oil into the pressure chamber between the lower body half and the elastic membrane inserted into it.

The invention offers means for generating the requisite pressure so that super-hard substances can be synthesized and powder and nanopowder can be sintered at high pressure. The device makes it possible in particular to generate high pressures and to employ heating; the pressures and the heating are sufficient to synthesize diamonds and other super-hard substances and to sinter powders, among them diamond powder as well.

Further expedient and advantageous embodiments of the invention will become apparent from the dependent claims.

According to the invention, it is provided that the pressure chambers in the lower body half and in the upper body half are connected to one another permanently, or in other words both in the closed and the opened state of the device, by means of a pipeline that is embodied in the form of a helical spring line.

A winding axis of the helical spring line is advantageously located here inside a common parting plane between the body halves. The common parting plane is defined by the surface on which the two body halves rest on one another when the device is closed.

The pipeline is preferably part of an oil line that additionally includes two connection line segments. One connection line segment is embodied in each body half. The connection line segments can be realized by means of bores in the body halves, which bores lead into the respective pressure chambers.

The oil line, including the two connection line segments and the helical spring line and connecting the pressure chambers in the lower body half and the upper body half to one another, is valveless in a particularly advantageous embodiment of the invention. Advantageously, it furthermore has no other moving parts. Torsion of the helical spring line, which is connected by both ends to the mouths of the connection lines at the two body halves, is not here a moving part in the sense of the above comment.

The connection line segments advantageously extend parallel to one another as well as parallel to the common parting plane. Advantageously, they exit the body halves laterally. Especially preferably, they exit laterally from the same side of the body halves as the side where the body halves are jointly connected to the helical spring line.

The present invention offers a device for synthesis of diamonds and other crystals which are grown under pressure by means of sintering of metal, ceramic diamond powders and nanopowders.

In a refinement of the invention, it is provided that the lower body half and the upper body half communicate with one another through a joint (20, 21), located on the body halves in a recess.

The joint axis advantageously coincides with the winding axis of the helical spring line.

In a refinement of the invention, it is especially preferred that the helical spring line includes the joint, or that the joint includes the helical spring line.

Preferably, it is provided that the helical axis of the helical spring line coincides with the joint axis of the joint.

Expediently, it can be provided that the device includes two opposed parts of a fastener, which press the body halves (2, 3) against one another.

It is especially preferable that the recess is covered by at least one of the two opposed parts of the fastener.

In a refinement of the present invention, it is provided that the helical spring line is located in the same recess as the joint. The size of the recess makes it possible to receive both the helical spring line and the joint and to displace the two opposed parts of the fastener that press the body halves against one another.

It is preferably provided that the inside diameter of the helical spring line ensures the same rate of change in oil pressure in the lower and upper body halves upon pressure buildup and reduction, and the helical spring line can withstand an oil pressure of at least 3000 atm.

It is especially preferably provided that it includes a split sphere, which can be inserted into the lower body half with the elastic membrane and which consists of eight sphere sectors (8), the truncated peaks of which form an octahedral void (9), which accommodates a growth chamber.

Expediently, it can be provided that it includes six sphere sectors in the form of truncated octahedral pyramids, which can be placed in the octahedral void and the truncated peaks of which form a chamber, in the form of a cube or cuboid, in which the growth chamber is located.

It is especially expedient in a refinement of the invention that it includes the following:
bus bars for supplying power to the heater in the growth chamber
and/or measurement current conductors, in order to transmit electrical signals of the temperature sensor and pressure indicator built into them;
and/or an opening and a channel in the upper body half, in order to expel air that is forced out by the oil the first time the device (1) is filled with oil;
and/or a recess in the lower body half and a similar recess in the upper body half for receiving a joint that ensures the opening and closing of the device;
and/or a joint, which is connected to the body halves in the recess.

In a refinement of the present invention, it is provided that the helical spring line) ensures an oil bypass between the body halves.

Expediently, it can be provided that the device is employed for growing synthetic diamonds.

The invention will now be described in further detail in terms of exemplary embodiments shown in the drawings.

In the drawings:

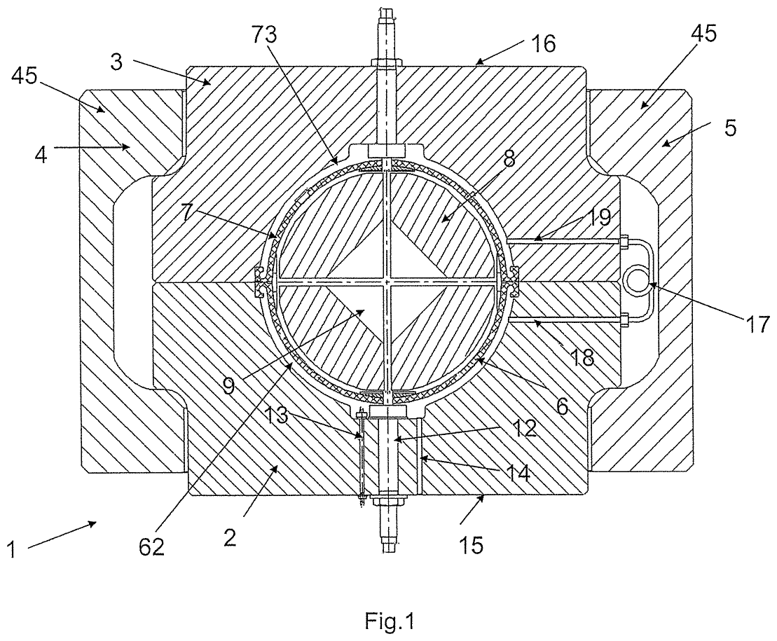

FIG. 1 shows a first exemplary embodiment of the invention in a vertical section;

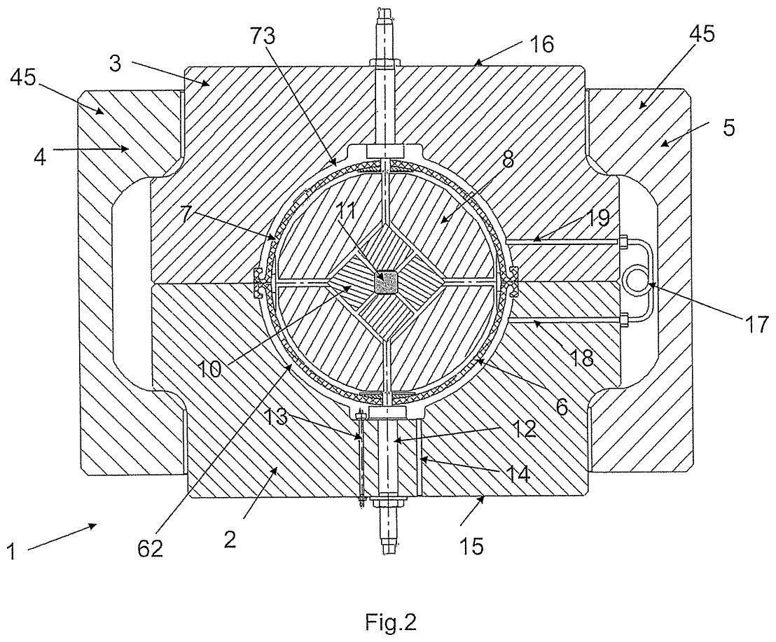

FIG. 2 shows a second exemplary embodiment of the invention in a vertical section;

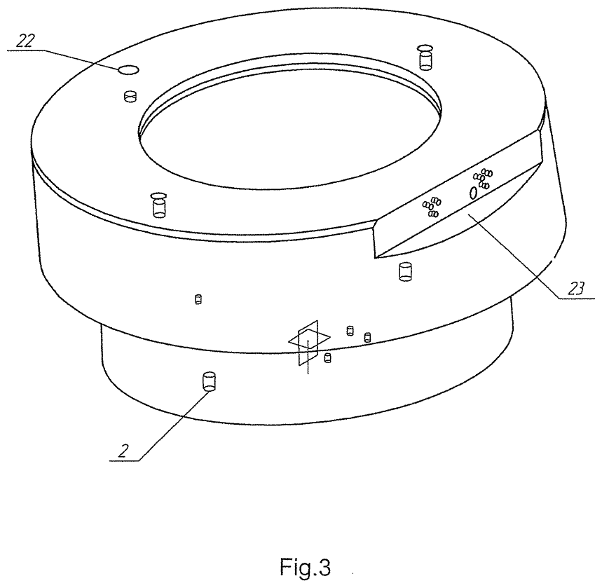

FIG. 3 shows a perspective view of the lower shell-shaped body half;

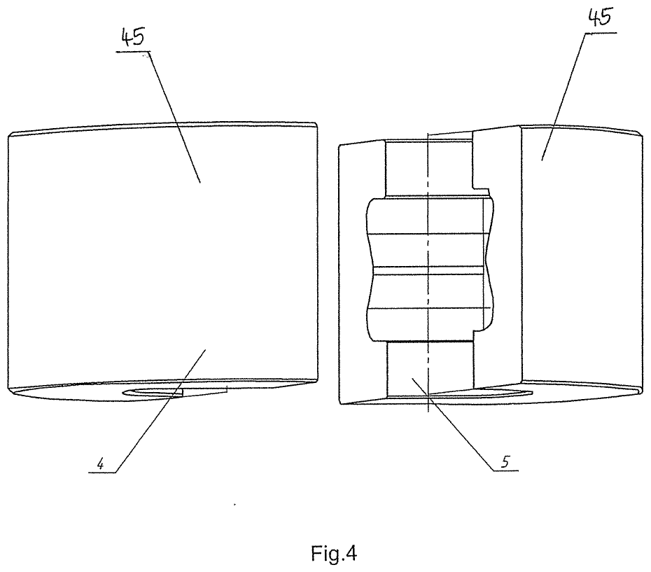

FIG. 4 shows a perspective view of the two-part fastener;

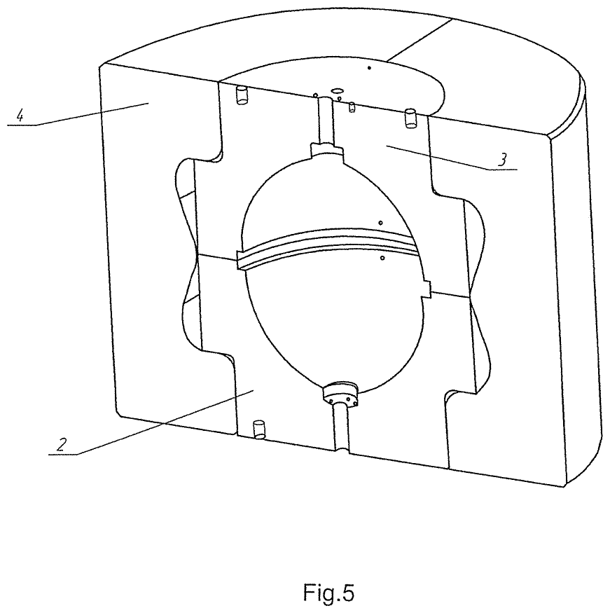

FIG. 5 shows a perspective view of a vertical section of the body halves and of the fastener in the closed state;

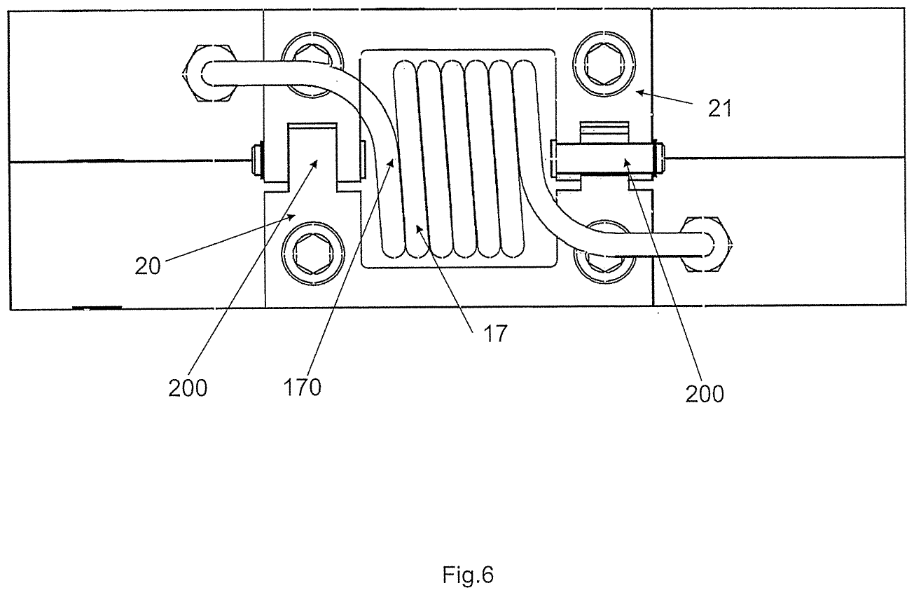

FIG. 6 shows a detailed view of the high-pressure pipeline or oil line in the form of a helical spring and of the joint in the vicinity of the connection of the lower body half and the upper body half; and

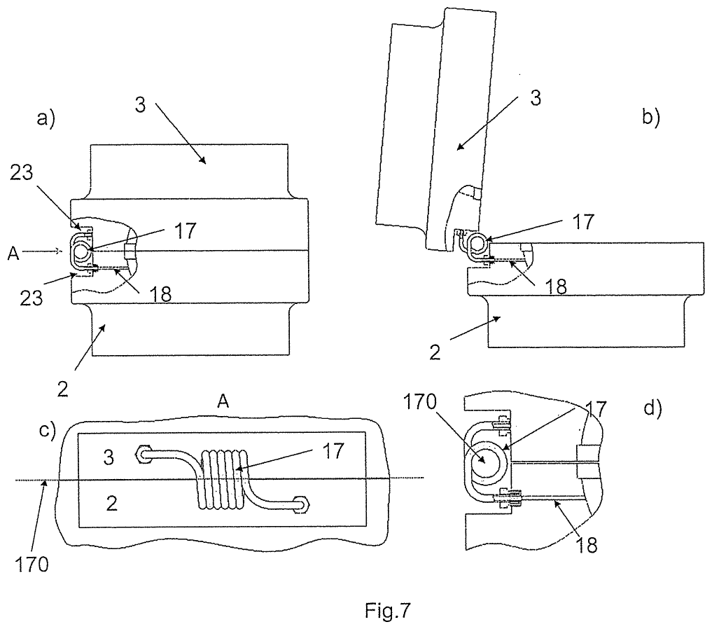

FIG. 7 shows the oil line, serving as an oil bypass between the body halves, in the form of a spiral, in partly sectional views of the lower body half and of the upper body half of the device:

FIG. 7a, in a partly sectional side view in the closed state;

FIG. 7b, in a partly sectional side view in the open, flipped-up state;

FIG. 7c, in a plan view on the vicinity of the connecting of the lower body half and the upper body half in the closed state; and

FIG. 7d, in a partly sectional side view of the vicinity of the connection of the lower body half and upper body half.

A device 1 according to the invention, shown entirely or in part in FIG. 1, FIG. 2, FIG. 3, FIG. 4, FIG. 5, FIG. 6, and FIG. 7, serves to generate high pressures in solid and fluid media. The device 1 includes a lower shell-shaped body half 2 and an upper shell-shaped body half 3. The device 1 furthermore includes a lower elastic membrane 6 and an upper elastic membrane 7, which are respectively inserted into the lower body half 2 and the upper body half 3. The respective body half 2, 3 and the respective membrane 6, 7 inserted into it each surround a pressure chamber 62, 73. Furthermore, the device 1 includes an opening and a channel 14 in the lower body half 2, in order to connect an oil line from an oil pump to the device and to pump the oil into the pressure chamber between the lower body half 2 and the elastic membrane 6 inserted into it. The pressure chambers 62, 73 in the lower body half 2 and in the upper body half 3 are connected by means of a line. The device 1 is distinguished in that the line permanently connects the pressure chambers 62, 73 in the lower body half 2 and in the upper body half 3 to one another both in the open and the closed state of the device. Furthermore, the device is distinguished in that it includes a pipeline, which extends outside the lower shell-shaped body half 2 and the upper shell-shaped body half 3 and is embodied in the form of a helical spring line 17.

The line advantageously includes a connection line segment 18 and a connection line segment 18. The two connection line segments 18, 19 communicate with one another by means of the helical spring line 17. The connection line segment 18 leads to the outside through the lower body half 2 from the pressure chamber 62, between the spherical surface of the lower body half 2 and the elastic membrane 6 inserted into the lower body half 2. The helical spring line 17 is connected by its one end to the outer mouth of the connection line segment 18. Toward the inside, the connection line segment 18 opens into the pressure chamber 62. The connection line segment 19 leads to the outside from the pressure chamber 73, between the spherical surface of the upper body half 3 and the elastic membrane 7 inserted into the upper body half 3, through the upper body half 3. The helical spring line 17 is connected by its remaining end to the outer mouth of the connection line segment 19. On the inside, connection line segment 19 opens into the pressure chamber 73.

The channel 14 as well as the connection line segments 18 and 19 are openings, formed for instance by bores, into the body halves 2, 3, which can also be called half shells, and which serve as channels for the oil. The connection line segments 18 and 19 here are segments of the line connecting the pressure chambers 62, 73 in the lower body half 2 and in the upper body half 3 permanently to one another, in both in the open and the closed state of the device 1. The channel 14 forms the oil line segment which connects the pressure chamber 62 in the lower body half 2 to the oil pump and which leads to the outside, through the lower body half 2, from the pressure chamber 62 between the spherical surface of the lower body half 2 and the elastic membrane 6 inserted into the lower body half 2.

Accordingly, both the channel 14 and the connection line segments 18 and 19 form segments of the entire, closed oil line system of the device 1.

The helical spring line 17 is preferably formed by a metal pipe, in the form of a helical spring, wound about a winding axis. The material of the helical spring line 17 is preferably high-strength steel or the like. Because it is in that form, the metal pipe behaves like a spring when the upper body half 3 of the device 1 is flipped up, away from the lower body half 2, preferably about the winding axis. The device 1 opens and closes by being flipped open and shut in hinged fashion. The helical spring line 17 formed for example by a metal pipe is secured to the outer mouths of the connection line segments 18 and 19 formed by holes in the lower and in the upper body halves 2, 3. The connection method will not be discussed at this point; as an example, a threaded connection of the kind that can be used to connect high-pressure lines can be mentioned. The helical spring line 17 also performs the function of the line, which can also be called the oil channel, that permanently connects the pressure chambers 62, 73 in the lower body half 2 and in the upper body half 3 to one another both in the open and the closed state of the device 1. The helical spring line 17 is a segment or part of the oil channel.

When pressure is exerted, oil is delivered from an oil pump through a high-pressure pipe, not shown, that opens into the channel 14. The high-pressure pipe is connected to the bottom of the channel 14, formed by a hole, in the lower half of the housing formed by the lower and the upper body halves 2, 3. The oil passes through the channel 14 into the pressure chamber 62 between the lower body half 2 and the flexible membrane 6. From this pressure chamber 62, the oil flows through the connection line segment 18 into the helical spring line 17, then into the connection line segment 19, and then into the pressure chamber 73 formed between the upper body half 3 and the elastic membrane 7. Thus at any given time, the same pressure is generated in the pressure chambers 62 and 73. In a similar way, if the pressure is reduced, the oil also leaves the pressure chambers 62, 73 but in the opposite direction.

The device 1 shown in FIGS. 1 and 2 is described here only as an example to make it apparent how the invention can be employed. The device 1 has the following elements:
a lower shell-shaped body half 2 (see FIG. 3) and an upper shell-shaped body half 3 similar to it;
two opposed parts 4, 5 of a fastener 45, which press the body halves 2, 3 against one another;
two elastic membranes 6 and 7, which are inserted and/or can be inserted into the spherical chambers of each of the shell-shaped body halves 2, 3; the respective body half 2, 3 and the membrane 6, 7 each inserted into a respective body half each surround one pressure chamber 62, 73;
a split sphere consisting of preferably eight spherical cutouts or spherical sector stumps, each forming a die, which are truncated inward toward the center of the sphere and for short are called sphere sectors 8 and which are inserted with an elastic membrane 6 into the half shell of the lower body half 2. The preferably eight sphere cutout or sphere sector stumps, each forming a die, surround a hollow chamber 9, which accommodates a growth chamber 11 serving the purpose of synthesis. The dies formed by the sphere sectors 8 are in truncated conical and/or truncated pyramid shape toward the hollow chamber 9. In the exemplary embodiment shown in FIG. 1, the dies formed by the eight sphere sectors 8 act directly on the central growth chamber 11 placed in the octahedral void 9;
in the exemplary embodiment shown in FIG. 2, between the sphere sectors 8, for instance eight of them, surrounding the void 9 of the split sphere and the growth chamber 11, there is a second stage of sphere sectors 10. These last sectors, inward toward the center of the sphere, accommodate and/or form a chamber accommodating and/or forming the growth chamber, this chamber being for example cubic, or a chamber in the form of a cuboid. Accordingly, in the exemplary embodiment shown in FIG. 2, instead of the growth chamber 11 directly, a second stage of likewise short truncated or cut-off sphere cutout stumps or sphere sector stumps, also called sphere sectors 10 for short, are located, inward toward the center of the sphere, in the void 9, which is octahedral for example, that is generated preferably by eight sphere sectors 8 of the split sphere. The second stage preferably consists of six octahedral pyramidal sphere sectors 10. In this case, the growth chamber 11 used for synthesis is inserted into a cubic chamber or into a chamber in the form of a cuboid, which is generated by truncated surfaces of the second stage of the octahedral sphere sectors 10.

The device 1 of FIG. 1 includes a lower shell-shaped body half 2 and an upper shell-shaped body half 3, a special fastener 45, two elastic membranes 6, 7, and a split sphere that can be inserted between the half shells with elastic membranes. The fastener 45 consists of two parts 4, 5 and prevents the body halves 2, 3 from coming apart when there is an oil pressure buildup. Elastic membranes 6, 7 are inserted into the sphere chambers of each of the shell-shaped body halves 2, 3.

The lower body half 2 and the membrane 6 inserted into it enclose a pressure chamber 62 that remains between them. In the same way, the upper body half 3 and the membrane 7 inserted into it enclose a pressure chamber 73. In other words, each body half 2, 3 and the respective membrane 6, 7 inserted into it, encloses a respective pressure chamber 62, 73.

The split sphere consists of eight sphere sectors 8, which act on a central growth chamber that is placed in an octahedral void 9.

A further embodiment is shown in FIG. 2. Instead of the growth chamber 11, a second stage of octahedral pyramidal sphere sectors 10 can be placed in the octahedral void 9, which is generated by eight sphere sectors 8 of the split sphere. In this case, the growth chamber 11 is placed in a cubic void or a chamber in the form of a cuboid 11, which is generated by the second stage of the octahedral sphere sectors 10. Thus as a result of the reduction in the surface area, a considerably increased pressure is exerted on the raw mixture found in the growth chamber 11. The raw mixture is used for growing diamonds or for reducing other crystals and for sintering metal, ceramic diamond powders and nanopowders.

To supply current for heating the raw mixture and water for cooling the sphere sectors, metal bus bars (power inputs) 12 can be built into the body halves 2, 3. The bus bars are insulated by the metal body halves 2, 3. A central opening is provided in order to allow the water to pass through. Moreover, measurement current conductors 13 are provided in the device 1 in order to transmit the signals of the temperature sensors and pressure indicators built into the device 1.

The pressure in the growth chamber 11 is generated by transmitting the pressure of the oil, delivered to the pressure chambers 62, 73 between the body halves 2, 3 and the elastic membranes 6, 7, to the split sphere via the membranes on sphere sectors 8. These then transmit this pressure to the growth chamber 11. In another embodiment according to FIG. 2, the sphere sectors 8 of the split sphere transmit the pressure the smaller octahedral sphere sectors 10 of the second stage. The smaller sphere sectors 10 then transmit the pressure into the growth chamber 11. The motion of the sphere sectors 8, 10 is triggered by the oil pressure that is transmitted via the elastic membrane 6, 7. During operation, a symmetrical and simultaneous motion of the sphere sectors 8 toward the center point of the split sphere occurs. For this to happen, a high-pressure oil pump must pump the oil, with the same throughput, simultaneously into the lower body half 2 and the upper body half 3 of the device 1. Furthermore, the oil upon a pressure reduction must leave the two body halves 2, 3 with the same throughput. In other words, the oil pressure in the pressure chambers 62, 73 in the upper body half 3 and the body half 2 should at every time be the same, both in a pressure buildup and upon a pressure reduction.

In some device described in the prior art, the oil is fed from the high-pressure pump into the lower body half via one oil line and into the upper body half via another oil line. FIG. 1 and FIG. 2 show an opening the lower body half 2, which communicates with a pipeline of the oil line. A similar opening (not shown in the drawings) can also be present in the upper body half. In the known devices, the second pipeline of the oil line is connected to this opening. This oil line is connected to the pump. During operation, the oil pressure can reach 2500 atm. This is why high-pressure pipelines and high-pressure connections are used for oil lines. The high-pressure pipeline and the high-pressure connections can during operation possibly be threatened at high pressures, if the pipeline breaks or detaches from the body half. The closed device and the displaced fastener on the lower body half 2 has only one free surface 15 at the bottom for attaching the high-pressure oil line. There is also a free surface 16 at the top of the upper body half 3. The high-pressure oil line running from the pump to the lower surface 15 of the lower body half is a relatively short high-pressure pipeline. This high-pressure pipeline under the device is covered and is not a danger if the pipeline should break or become detached at high oil pressure.

The high-pressure oil line running from the pump to the upper surface 16 of the upper body half is a considerably longer high-pressure pipeline. This pipeline is laid on the outside of the device. At high oil pressure, this longer pipeline can be dangerous if it should break or become detached. Along with this shortcoming, the high-pressure pipeline that connects the pump to the upper surface 16 of the upper body half should be long enough that the device can be opened and shut. The upper body half 3 and the lower body half 2 are joined to one another by means of a joint, which is represented in FIG. 6 by the joint connections 20, 21. The joint ensures that the upper body half 3 can be flipped open and shut at the joint. The pipeline that can be connected to the upper body half 3 must enable the capability of the upper body half 3 to move when the device 1 is being opened and closed. To be able to perform such a movement, the pipeline must be long enough to ensure a requisite degree of bending, for flipping the upper body half 3 (lid) of the device open and shut at the joint. The degree of bending of the high-pressure pipeline must not exceed a size that both in the motion of the upper body half 3 and in high-pressure operation brings about higher stresses than are allowable in the high-pressure pipeline and in the high-pressure connections.

Thus the use of the additional oil line connecting the high-pressure pump and the upper body half creates a risk if the high-pressure oil line breaks or detaches. Furthermore, the use of the long high-pressure pipeline makes maintenance less convenient and adversely affects the appearance of the device.

In the other known embodiment, a special bypass valve is provided between the lower body half 2 and the upper body half 3 in order to ensure simultaneous pumping of oil from the pump to the two body halves and to ensure the pressure buildup in the device. The bypass valve is built into the openings 22. The openings are located on the surfaces, belonging to one another, of the lower body half and of the upper body half (FIG. 3), where the lower and the upper parts of the bypass valve are located. When the device is flipped shut (FIGS. 1, 2, 5), the bypass valve is opened. If the device is opened, the bypass valve closes, so that in the open state the oil does not flow out of the two body halves. Upon a pressure buildup, the oil flows out of the lower body half 2 into the upper body half 3, or upon pressure reduction vice versa from the upper body half 3 into the lower body half 2. The obvious advantages of this construction are its safety, ease of operation of the device, and a better appearance. The device has the shortcoming that such a bypass valve includes moving parts, which operate at high pressure. This leads to wear of those parts. Consequently, the valve cannot ensure complete sealing. This causes oil leaks both under pressure and upon opening of the device and leads to constant maintenance work as well as periodic replacement of the valve parts.

In order to overcome all the shortcomings of the known constructions of the device, according to the present invention a novel construction for the oil supply into the upper body half 3, in order to generate the pressure in the device 1, is proposed.

To avoid the necessity of
using an additional oil line, which connects the high-pressure pump to the upper body half, and of
inserting a high-pressure bypass valve between the body halves,
   it is proposed according to the invention that the required oil bypass between the body halves 2, 3 be embodied with the aid of a special oil line, which permanently connects the pressure chamber 62 in the lower body half 2 and the pressure chamber 73 in the upper body half 3 of the device 1.

The proposed oil line is fixedly attached to the lower body half 2 and to the upper body half 3. Preferably, it can reroute the oil at a pressure of at least 2500 bar. The bypass oil line must be as short as possible and must have a rather large internal cross section in order to ensure the same oil pressure simultaneously in both body halves upon pressure buildup and upon pressure reduction. In the construction of the device 1, the bypass oil line must also be covered, in order to ensure safe operation under pressure, in order not to cause hindrances in operation of the system, in order to enable the motion of the upper body half 3 at the joint 20, 21 so that the device 1 can be opened and shut, and in order not to adversely affect the appearance of the device 1.

To meet the prerequisites recited above, it is proposed that the oil line be embodied in the form of a helical spring in the vicinity of the joint connection of the body halves 2, 3. During operation, the oil is fed into the lower body half 2 and flows from there via the helical spring line 17 into the upper body half 3. When the device 1 is opened and shut, the helical spring line 17 is subjected to stress with regards to twisting, and this makes it possible for the upper body half 3 to move as needed.

Accordingly, it is provided by the invention that the pressure chambers 62, 73 in the lower body half 2 and in the upper body half 3 communicate with one another permanently, that is, both in the closed and the open state of the device 1, by way of the pipeline embodied in the form of a helical spring line 17.

Via the pipeline, the pressure chamber 62 in the lower body half 2 and the pressure chamber 73 in the upper body half are in a state of permanent communication. Via the pipeline, the pressure chamber 62 in the lower body half 2 and the pressure chamber 73 in the upper body half 3 communicate permanently with one another.

Because the pipeline permanently connects the pressure chambers 62, 73 in the lower body half 2 and in the upper body half 3 with one another, the escape of oil when work is being done with the device 1, in particular when it is being opened, is prevented. Furthermore, the pipeline permanently connecting the pressure chambers 62, 73 in the lower body half 2 and in the upper body half 3 with one another provides the prerequisite that allows the pressure chambers 62, 73 in the lower body half 2 and in the upper body half 3 to communicate with one another in valveless fashion.

The pipeline is especially advantageously embodied as valveless. Accordingly, no valve is seen between the pressure chambers 73 in the lower body half 2 and the upper body half 3 along the pipeline.

Being valveless ensures that during the pressure buildup, pressure maintenance, and pressure reduction, no differences in pressure between the pressure chambers 62, 73 in the lower body half 2 and the upper body half 3 can occur. This assures that the sphere sectors that form dies of a split sphere all synchronously execute a symmetrical motion during the pressure buildup and during the pressure reduction. The split sphere can be inserted into the body halves 2, 3 with the elastic membranes 6, 7. The sphere sectors form a void that accommodates the growth chamber. Because it is ensured that the sphere sectors all simultaneously execute a symmetrical motion, no skewed position between them at all occurs. In comparison to the prior art, the result is no break of the inner dies and thus no outbreak of material whatever in the growth chamber. This makes for a lower rejection rate of the synthetic product, produced in the growth chamber and known as a product of synthesis, and also enhances the quality of the synthetic product. This ensures that, by means of the device, synthetic products have consistent homogeneity, and high quality can be achieved.

So that the pipeline can follow along with the relative motion between the lower body half 2 and the upper body half 3 upon opening and closing of the device 1, the pipeline is embodied in the form of a helical spring line 17. As a result, it can be embodied without moving parts. This, along with being valveless, ensures that, at the high pressures required for making a synthetic product, excessive wear of moving parts along the oil line between the pressure chambers 62, 73 cannot occur. The occurrence of such wear of moving parts would impair or even entirely prevent the pressure equalization between the pressure chambers 62, 73 in the lower and upper body halves 2, 3. By dispensing with moving parts, the disruptions of a uniform pressure buildup and pressure reduction in the pressure chambers 62, 73 in the lower and upper body halves 2, 3, which worsen the quality of the synthetic product, are precluded.

A winding axis of the helical spring line is advantageously located here inside a common parting plane between the two body halves 2, 3. The common parting plane is laid out by means of the surface on which the two body halves 2, 3 rest on one another when the device 1 is shut.

The pipeline is preferably part of an additional line that includes two connection line segments 18, 19. One connection line segment 18, 19 is embodied in each body half. The connection line segments 18, 19 can be realized by means of bores in the body halves 2, 3, with each bore leading into the respective pressure chamber 62, 73.

In an especially advantageous embodiment of the invention, the line including the two connection line segments 18, 19 and the helical spring line 17 that connects the pressure chambers 62, 73 in the lower body half 2 and the upper body half 3 with one another is valveless. Advantageously, it furthermore has no other moving parts. Torsion of the helical spring line 17 connected by both of its ends to the mouths of the connection lines 18, 19 at the two body halves 2, 3 is not, in the sense of the above comment, a moving part.

The connection line segments 18, 19 advantageously extend parallel to one another as well as parallel to the common parting plane. They advantageously emerge laterally from the body halves. Especially preferably, they emerge from the body halves laterally on the same side where they are joined to one another by the helical spring line.

The joint axis coincides with the winding axis of the helical spring line.

In summary, for attaining the stated object, the invention advantageously has the following features:
The oil line includes the connection line segments 18 and 19 as well as the helical spring line 17.
The oil line connects the pressure chambers 62, 73 permanently with one another. As a result, the pressure chambers 62, 73, via the oil line, communicate with one another without interruption, both in the open and the closed states of the device 1 and in all intermediate positions.
The oil line is valveless; that is, it is embodied without valves.
The oil line makes do without moving parts.
The helical spring line 17 is subjected to torsional stress only upon opening and closing of the device 1 but otherwise does not move.
The connection line segments 18, 19 extend parallel to one another as well as parallel to a common parting plane between the lower body half 2 and the upper body half 3.
The connection line segments 18, 19 are realized by means of bores in the lower body half 2 and the upper body half 3.
The connection line segments 18, 19 emerge from the lower body half 2 and the upper body half 3 on the same side where they are each connected to the helical spring line 17 and via the helical spring line 17 to one another.
The joint axis coincides with the winding axis of the helical spring line 17.
The joint axis can be in the form of a shaft of a joint that movably connects the two body halves.

Further advantages over the prior that go beyond a complete achievement of the stated object are these:
The pressure chamber 62, between the spherical surface of the lower body half 2 and the elastic membrane 6 inserted into it, and the pressure chamber 73, between the spherical surface of the upper body half 3 and the elastic membrane 7 inserted into it, are permanently connected to one another via the oil line. That is, they are permanently connected both in the open and the closed state as well as in the intermediate position of the device 1. As a result, upon opening and closing of the device 1, oil cannot escape. Furthermore, as a result, valves and moving parts that contribute to the makeup as well as the function of the device are dispensed with. Because the oil line includes a pipeline which is embodied in the form of a helical spring line 17, the oil line can override the relative motion between the lower body half 2 and the upper body half 3 upon opening and closing of the device 1 without requiring moving parts for that purpose.
By completely omitting moving parts, an impairment or hindrance of a pressure equalization between the pressure chambers 62, 73 in the lower and upper body halves 2, 3 is precluded. As a result, a permanently equal pressure in the pressure chambers 62, 73 in the lower and upper body halves 2, 3 is ensured during the pressure buildup, pressure maintenance, and pressure reduction throughout the entire synthesis process. Thus a consistent quality of the synthetic product is ensured, since no skewing occurs between the sphere sectors 8 that surround the void 9 that accommodates the growth chamber.

Pressure differences between the pressure chambers 62, 73 caused by moving parts lead to asymmetrical motions of the sphere sectors 8 that form dies. Asymmetrical motions cause skewing between the sphere sectors 8. Even very slight skewing, given the necessary high pressure for operating the growth chamber, cause breakage of the internal dies and/or an escape of material in the growth chamber. This makes the synthetic product produced in the growth chamber unusable.

The device 1 thus contributes to reducing rejection in the production of synthetic products, along with a drop in costs for production. The cost reduction is due to the low rejection rate and simple handling. The simpler handling results in greater synchronization, in accordance with a higher number of synthetic products that can be produced within a given span of time. The greater synchronization is achieved since upon opening and closing of the device 1, compared to the prior art, attention does not have to be paid to the escape of oil or hydraulic fluid. The reason no attention has to be paid to the escape of oil or hydraulic fluid is that the helical spring line 17 permanently connects the pressure chambers 62, 73 in the upper and lower body halves 2, 3 to one another in both the open and closed state of the device 1.

The device 1 can furthermore include the following:
metal bus bars 12, which are electrically insulated from the preferably metal body halves, with a central opening for allowing water to pass through; the bus bars supply power to a heater in the growth chamber in order to heat the raw mixture; the water runs through the opening into the bus bars in order to cool the sphere sectors;
measurement current conductors 13, for transmitting signals from the temperature sensors and pressure indicators built into the device 1.

The device 1 functions as follows:

After the device 1 is loaded and closed, the high-pressure pump pumps the oil into the lower body half 2 via an opening in the channel 14. The oil flows via the channel 14 into a pressure chamber 62 between the spherical surface of the lower body half 2 and the elastic membrane 6 inserted into that body half. The body halves 2, 3 and the respective membranes 6, 7 inserted into them each surround one pressure chamber 62, 73.

The pressure chamber 62 in the lower body half 2 communicates with the pressure chamber 73 in the upper body half 3 by means of an oil line.

The oil line connects the pressure chambers 62, 73 in the lower body half 2 and in the upper body half 3 permanently with one another both in the open and the closed state of the device 1. The oil line includes a pipeline extending outside the lower shell-shaped body half 2 and the upper shell-shaped body half 3, which pipeline is embodied in the form of a helical spring line 17.

The pipeline, acting as an oil line and known as a helical spring line 17, is embodied in the form of a spiral extending along and encircling a winding axis. The embodiment according to the invention of the helical spring line 17 is shown in FIGS. 1 and 2 and again in more detail in FIGS. 6 and 7.

Advantageously, the oil line furthermore includes a first connection line 18, preferably formed by a bore, that extends from the pressure chamber 62 in the lower body half 2 through the lower body half 2 and leading to the outside. Furthermore, the oil line advantageously includes a second connection line 19, also preferably formed by a bore, leading from the pressure chamber 73 in the upper body half 3 through the upper body half 3 and to the outside.

Thus the oil line advantageously includes a first connection line 18, leading through the lower body half 2 between the pressure chamber 62 in the lower body half 2 and the helical spring line 17, and a second connection line 19, leading through the upper body half 3, between the pressure chamber 73 in the upper body half 3 and the helical spring line 17.

Especially advantageously, the line connecting the pressure chambers 62, 73 in the lower body half 2 and in the upper body half 3 is embodied without valves.

The connection of the pressure chambers 62, 73 in the lower body half 2 and in the upper body half 3 by means of the pipeline is without valves of whatever type, whether backflow valves or bypass valves or overpressure valves, so that moving parts that quickly wear at high pressure are not needed, thus ensuring a uniform and synchronized pressure increase and reduction in the pressure chambers 62, 73 in the lower body half 2 and in the upper body half 3.

Even the slightest time lag upon pressure rise and reduction between the pressure chambers 62, 73 in the lower body half 2 and in the upper body half 3 leads to an inconsistent displacement of the sphere sectors 8. If, to produce a synthetic product, very high pressures can be achieved with the device, then such inconsistent displacements must be averted, since at the prevailing very high pressures they would lead to stresses between the sphere sectors 8 and finally cause these sphere sectors to break.

The helical spring line 17 is preferably located and secured in a common recess 23. The common recess is formed by the recess 23 of the lower and upper body halves 2, 3 that are pressed together (FIGS. 3 and 7). The joint 20, 21 (FIGS. 6 and 7) is located and secured in the same recess 23. The joint 20, 21 makes it possible to open and close the device 1 by flipping shutting the upper housing secured to the joint 20, 21 open and shut.

The helical axis 170 of the helical spring line 17 preferably coincides with the joint axis 200 of the joint 20, 21 (FIG. 6, FIG. 7c, FIG. 7d).

FIG. 7a shows the helical spring line 17, serving as an oil line between the pressure chambers 62, 73, in the closed state of the system. FIG. 7b shows the helical spring line 17 in the open state, with the body halves flipped up at the joint 20, 21. The helical spring line 17 is subjected to torsional stress and ensures the requisite motion of the upper body half 3 relative to the lower body half 2 about the joint axis 200. The recess 23 makes it possible to displace the parts 4, 5 of the fastener 45 tightly against the closed body halves 2, 3 and to keep the lower and upper body halves 2, 3 firmly shut upon a pressure buildup.

The oil arriving in the pressure chamber 62 between the spherical surface of the lower body half 2 and the elastic membrane 6 flows via the helical spring line 17 into the pressure chamber 73 between the spherical surface of the upper body half 3 and the elastic membrane 7. Thus an equal oil pressure is generated simultaneously in both the pressure chamber 62 in the lower body half 2 and the pressure chamber 73 in the upper body half 3.

The pressure of the oil delivered to the pressure chambers 62 and 73 between the body halves 2 and 3 and the elastic membranes 6 and 7 is transferred via the membranes 6, 7 to the sphere sectors 8 of the split sphere. The sphere sectors 8 simultaneously shift toward the center point and thus generate the pressure in the void 9 accommodating the growth chamber 11 (FIG. 1).

In the exemplary embodiment shown in FIG. 2, the sphere sectors 8 of the split sphere transmit the motion to the smaller octahedral sphere sectors 10 of the second stage. They in turn shift simultaneously toward the center point of the sphere and thus generate the pressure in the growth chamber 11. A surface A1 of the outer face of the split sphere, which split sphere is under oil pressure, is considerably larger than a surface A2 of the growth chamber 11. As a result, the pressure in the growth chamber 11 exceeds the oil pressure substantially, and in proportion to the surface area ratio A2/A1.

At all times during the pumping operation, the same oil pressure always occurs in the pressure chambers 62, 73 in the lower and upper body halves 2, 3. Consequently, a symmetrical motion of the sphere sectors 8 toward the center point of the split sphere comes about. Similarly, the sphere sectors 8 of the split sphere upon an oil pressure reduction simultaneously symmetrically and at the same speed move apart from one another in the lower body half 2 and in the upper body half 3. This kind of simultaneous, symmetrical motion of the sphere sectors 8 precludes any offsets (skewed positions) in the system of sphere sectors 8 and ensures the trouble-free function of the device 1.

The device 1 makes it possible to produce the pressures in the growth chamber 11 that are required for the diamond synthesis.

One can recognize that the invention in any case is realized by a device 1 for generating high pressures in solid and liquid media, and especially for growing a synthetic diamond, which device has the following:
a lower shell-shaped body half 2 and an upper shell-shaped body half 3;
two opposed parts 4, 5 of the closure 45, which press the body halves 2, 3 against one another;
a lower elastic membrane 6 and an upper elastic membrane 7, which are each insertable into the lower body half 2 and the upper body half 3 respectively;
a split sphere which can be inserted into the lower body half 2 with the elastic membrane 6 and consists of eight sphere segments 8, the truncated tips of which form an octahedral void 9;
six sphere segments 10, which can be placed in the octahedral void 9 and are in the form of truncated octahedral pyramids, the truncated tips of which form a chamber in the shape of a cube or cuboid;
a growth chamber 11, which is located in the cubic chamber,
bus bars 12 for supplying the heater in the growth chamber;
measurement current conductors 13, for transmitting electrical signals of the temperature sensor and pressure indicator that are built into the device;
an opening and a channel 14 in the lower body half 2, for attaching an oil line and an oil pump to the device 1 and for pumping the oil into the pressure chamber 62 between the lower body half 2 and the elastic membrane 6;
a similar opening and channel in the upper body half 3, for letting out the air displaced by the oil upon the initial filling of the device;
a recess 23 in the lower body half 2 and a similar recess 23 in the upper body half 3 for receiving a joint 20, 21, that ensures the opening and shutting of the device 1; and
a joint 20, 21, which is attached to the body halves 2, 3 in the recess 23.

The device 21 is preferably distinguished in that:
the pressure chamber 62 in the lower body half 2 and the pressure chamber 73 in the upper body half 3 communicate permanently with one another by means of a pipeline, which ensures an oil bypass between the pressure chambers 62, 73 in the body halves 2, 3 and is embodied in the form of a helical spring line 17; and/or
that the helical spring line 17 is subjected to stress with regard to twisting and reversed rotation, enabling the upper body half 3 to be flipped open and shut on the joint 20, 21, and/or
that each of the body halves 2, 3 has its own additional opening and its own channel formed by the connection line segment 18 in the lower body half 2 and by the connection line segment 19 in the upper body half 3, in order to attach the helical spring line 17 and to enable the flow of oil between the helical spring line 17 and the pressure chamber 62, formed by the lower body half 2 and the elastic membrane 6, and the pressure chamber 73, formed by the upper body half 3 and the elastic membrane 7.

The additional opening is formed here by the mouths of the connection line segments 18, 19.

The invention offers means for generating the requisite pressure so that super-hard substances can be synthesized and that powder and nanopowder can be sintered at high pressure. The device 1 makes it possible in particular to generate high pressures, and to use heat, both of which are sufficient for synthesizing diamonds and other super-hard substances and sintering powder, including diamond powder.

### LIST OF REFERENCE NUMERALS

1 Apparatus
2 Lower body half
3 Upper body half
4 Part of the fastener
5 Part of the fastener
6 Elastic membrane of the lower body half
7 Elastic membrane of the upper body half
8 Sphere sector of the split sphere
9 Octahedral void for receiving the growth chamber or the second stage of the octahedral sphere sectors
10 Octahedral sphere sector
11 Growth chamber
12 Current conductor
13 Measurement current conductor
14 Oil supply channel for the lower body half
15 Surface of the lower body half, available for the attachment of the external oil line
16 Surface of the upper body half, available for attaching the external oil line
17 Helical spring pipeline: pipeline in the form of a helical spring for the oil bypass between the lower and the upper body half
18 Connection line between the lower body half and the helical spring line for the oil bypass
19 Connection line between the upper body half and the helical spring line for the oil bypass
20 Joint connection between the lower body half and the upper body half
21 Joint connection between the lower body half and the upper body half
22 Opening for mounting the bypass valve in the device of the prior art
23 Recess for receiving the joint and the helical spring line for the oil bypass
45 Fastener
62 Pressure chamber
73 Pressure chamber
170 Helical axis
200 Joint axis

1. A device (1) for generating high pressures in solid and liquid media, including:
a lower shell-shaped body half (2) and an upper shell-shaped body half (3),
a lower elastic membrane (6) and an upper elastic membrane (7), which are each inserted into the lower body half (2) and into the upper body half (3), and the respective body half (2, 3) and the respective membrane (6, 7) inserted into its each surround a pressure chamber (62, 73),
an opening and a channel (14) in the lower body half (2), in order to attach an oil line from an oil pump to the device and to pump the oil into the pressure chamber between the lower body half (2) and the elastic membrane (6) inserted into it,
wherein the pressure chambers (62, 73) in the lower body half (2) and in the upper body half (3) communicate by means of a line,
characterized in that
the line connects the pressure chambers (62, 73) in the lower body half (2) and the upper body half (3) permanently with one another in both the open and the closed state of the device and includes a pipeline, which is embodied in the form of a helical spring line (17) and extends outside the lower shell-shaped body half (2) and the upper shell-shaped body half (3).

2. The device of claim 1,
wherein the line furthermore includes a first connection line (18), extending through the lower body half (2) and between the pressure chamber (62) in the lower body half (2) and the helical spring line (17), and a second connection line (19), extending through the upper body half (3) and between the pressure chamber (73) in the upper body half (3) and the helical spring line (17).

3. The device of claim 1,
wherein the line connecting the pressure chambers (62, 73) in the lower body half (2) and in the upper body half (3) is valveless.

4. The device of claim 1,
characterized in that
the lower body half (2) and the upper body half (3) communicate with one another through a joint (20, 21), located on the body halves in a recess (23).

5. The device of claim 4,
characterized in that
the helical spring line (17) includes the joint (20, 21), or the joint (20, 21) includes it.

6. The device of claim 4,
characterized in that
the helical axis (170) of the helical spring line (17) coincides with the joint axis (200) of the joint (20, 21).

7. The device of claim 1,
characterized in that
it includes two opposed parts (4, 5) of a fastener (45), which press the body halves (2, 3) against one another.

8. The device of claim 7,
characterized in that
the recess (23) is covered by at least one of the two opposed parts (4, 5) of the fastener (45).

9. The device of claim 7,
characterized in that
the helical spring line (17) is located in the same recess (23) as the joint (20, 21) and the size of the recess (23) makes it possible to receive both the helical spring line (17) and the joint (20, 21) and to displace the two opposed parts (4, 5) of the fastener that press the body halves (2, 3) against one another.

10. The device of claim 1,
characterized in that
the inside diameter of the helical spring line (17) ensures the same rate of change in oil pressure in the lower and upper body halves (2, 3) upon pressure buildup and reduction, and the helical spring line (17) can withstand an oil pressure of at least 3000 atm.

11. The device of claim 1,
characterized in that
it includes a split sphere, which can be inserted into the lower body half (2) with the elastic membrane (6), which split sphere consists of eight sphere sectors (8), the truncated peaks of which form an octahedral void (9), which accommodates a growth chamber (11).

12. The device of claim 11,
characterized in that
it includes six sphere sectors (10) in the form of truncated octahedral pyramids, which can be placed in the octahedral void (9) and the truncated peaks of which form a chamber, in the form of a cube or cuboid, in which the growth chamber (11) is located.

13. The device of claim 1,
characterized in that
it includes the following:
bus bars (12) for supplying power to the heater in the growth chamber (11) and/or
measurement current conductors (13), in order to transmit electrical signals of the temperature sensor and pressure indicator built into them, and/or
an opening and a channel in the upper body half (3), in order to expel air that is forced out by the oil the first time the device (1) is filled with oil, and/or
a recess (23) in the lower body half (2) and a similar recess (23) in the upper body half (3) for receiving a joint (20, 21) that ensures the opening and closing of the device (1),
and/or
a joint (20, 21), which is connected to the body halves (2, 3) in the recess (23).

14. The device of claim 1,
characterized in that
the helical spring line (17) ensures an oil bypass between the body halves,
the helical spring line (17) is subjected to stress with regard to twisting and reversed rotation, so that the upper body half (3) can be flipped open and shut at the joint,
that each of the body halves (2, 3) has one additional opening each and one channel, in order to attach the helical spring line (17) and to enable the oil flow between the helical spring line (17) and the pressure chamber (62) formed by the lower body half (2) and the elastic membrane (6) and the pressure chamber (73) formed by the upper body half (3) and the elastic membrane (7).

15. The device of claim 1,
characterized in that
it is provided for growing synthetic diamonds.
